(19) United States
(12) Patent Application Publication
(10) Pub. No.: US 2016/0026049 A1
(43) Pub. Date: Jan. 28, 2016

(54) THIN-FILM TRANSISTOR SUBSTRATE AND DISPLAY PANEL HAVING THE SAME

(71) Applicant: Samsung Display Co., Ltd., Yongin-City (KR)

(72) Inventors: Seung-Hyun Park, Seoul (KR); Jun-Ho Song, Seongnam-si (KR); Jean-Ho Song, Yongin-si (KR)

(21) Appl. No.: 14/585,984

(22) Filed: Dec. 30, 2014

(30) Foreign Application Priority Data
Jul. 28, 2014 (KR) 10-2014-0095892

(51) Int. Cl. G02F 1/1362; G02F 1/1368; H01L 27/12

(52) U.S. Cl. CPC G02F 1/136286; H01L 27/124; H01L 27/1248; G02F 1/1368; G02F 1/136209; G02F 2001/136222

(57) ABSTRACT

A thin-film transistor substrate includes a base substrate, a gate line, a data line, a thin-film transistor, an organic insulating pattern and a common electrode. The base substrate includes a plurality of pixel areas. The gate line is disposed on the base substrate, and the gate line is extended in a first direction. The data line is disposed on the gate line, and the data line is extended in a second direction crossing the first direction. The thin-film transistor is connected to the gate line and the data line. The organic insulating pattern covers the data line and the thin-film transistor, and the organic insulating pattern includes an opening overlapping with the pixel areas. The common electrode is disposed on the base substrate. Thus, an organic insulating layer in a pixel area may be partially removed, so that a yellowish screen may be prevented, thereto improve a display quality. In addition, an organic insulating pattern may be formed on a data pattern, a coupling capacitance between the data pattern and a common electrode may be prevented or decreased, thereto prevent a data signal delay.

### CLAIM OF PRIORITY

This application claims priority to Korean Patent Application No. 10-2014-0095892, filed on Jul. 28, 2014, and all the benefits accruing therefrom under 35 U.S.C. § 119, the contents of which are herein incorporated by reference in their entireties.

### BACKGROUND OF THE INVENTION

1. Field of the Invention

Exemplary embodiments of the inventive concept relate to a photo-alignment composition and a method of manufacturing a display panel using the same. More particularly, exemplary embodiments of the inventive concept relate to a photo-alignment composition capable of improving a hardness of an alignment layer and removing an afterimage of a display panel and a method of manufacturing a display panel using the photo-alignment composition.

2. Description of the Related Art

A liquid crystal display apparatus is one of a flat panel display FPD, which is used broadly recently. Examples of the flat panel display include, but are not limited to, a liquid crystal display (“LCD”), a plasma display panel (“PDP”) and an organic light emitting display (“OLED”).

The liquid crystal display apparatus applies voltages to molecules of liquid crystal to adjust arrangements of the molecules thereby changing optical characteristics of a liquid crystal cell such as birefringence, optical activity, dichroism and light scattering to display an image.

The liquid crystal display apparatus includes a thin-film transistor TFT array substrate including a pixel electrode, a color filter substrate including a common electrode, and a liquid crystal layer between the substrates. An electric field is generated between the pixel electrode and the common electrode, a transmissivity of each pixel may be controlled by arrangements of the liquid crystal layer which is changed by the electric field thus displaying an image.

Recently, PVA (patterned vertical alignment) mode and IPS (in-plane switching) mode are used to improve side visibility of the liquid crystal display apparatus. However, a liquid crystal display apparatus by PVA mode may have an after-image on a screen, and side visibility may be hard to improve. A liquid crystal display apparatus by IPS mode may have low brightness on a screen. Therefore, a liquid crystal display apparatus by PLS (plane to line switching) mode is used to improve side visibility and brightness.

The liquid crystal display apparatus by PLS mode includes an organic insulating layer between a data line and a common electrode, so that an unnecessary coupling capacitance between the data line and the common electrode may be decreased, thus capable of stable pixel charge. Thus, a ripple voltage, a kick-back voltage between a gate signal, a data signal and a common electrode may be reduced. However, when the organic insulating layer is formed in the pixel area, the organic insulating layer includes an organic material so that a yellowish screen may be displayed.

### BRIEF SUMMARY OF THE INVENTION

Exemplary embodiments of the inventive concept provide a thin-film transistor substrate capable of improving a display quality, and preventing a data signal delay.

Exemplary embodiments of the inventive concept also provide a display panel including the thin-film transistor.

According to an exemplary embodiment, a thin-film transistor substrate includes a base substrate, a gate line, a data line, a thin-film transistor, an organic insulating pattern and a common electrode. The base substrate includes a plurality of pixel areas. The gate line is disposed on the base substrate, and the gate line is extended in a first direction. The data line is disposed on the gate line, and the data line is extended in a second direction crossing the first direction. The thin-film transistor is connected to the gate line and the data line. The organic insulating pattern covers the data line and the thin-film transistor, and the organic insulating pattern includes an opening overlapping with the pixel areas. The common electrode is disposed on the base substrate.

In an exemplary embodiment, the organic insulating pattern may cover the gate line.

In an exemplary embodiment, a color filter may be disposed between adjacent data lines.

In an exemplary embodiment, a black matrix may overlap with the gate line, the data line and the thin-film transistor.

In an exemplary embodiment, the organic insulating pattern may include a photosensitive organic material.

In an exemplary embodiment, a permittivity (ε) of the organic insulating pattern may be equal to or less than 4.5.

In an exemplary embodiment, a gate insulating layer may cover the gate line. A first passivation layer may cover the data line. A second passivation layer may cover the common electrode. A pixel electrode may be disposed on the second passivation layer, and the pixel electrode may overlap with the pixel areas.

In an exemplary embodiment, the pixel electrode may be disposed between adjacent data lines.

In an exemplary embodiment, the pixel electrode may have a slit pattern.

In accordance with an exemplary embodiment, a display panel includes a first substrate, a second substrate, a gate line, a data line, a thin-film transistor, an organic insulating pattern and a common electrode. The first substrate includes a plurality of pixel areas. The second substrate faces the first substrate. The gate line is disposed on the first substrate, and is extended in a first direction. The data line is disposed on the gate line, and is extended in a second direction crossing the first direction. The thin-film transistor is connected to the gate line and the data line. The organic insulating pattern covers the data line and the thin-film transistor, and includes an opening overlapping with the pixel areas. The common electrode is disposed on the first substrate.

In an exemplary embodiment, the organic insulating pattern may cover the gate line.

In an exemplary embodiment, a color filter may be disposed between adjacent data lines.

In an exemplary embodiment, a black matrix may overlap with the gate line, the data line and the thin-film transistor.

In an exemplary embodiment, the organic insulating pattern may include a photosensitive organic material.

In an exemplary embodiment, a permittivity (ε) of the organic insulating pattern may be equal to or less than 4.5.

In an exemplary embodiment, a gate insulating layer may cover the gate line. A first passivation layer may cover the data line. A second passivation layer may cover the common electrode. A pixel electrode may be disposed on the second passivation layer, and the pixel electrode may overlap with the pixel areas.

In an exemplary embodiment, the pixel electrode may be disposed between adjacent data lines.

In an exemplary embodiment, the pixel electrode may have a slit pattern.

In such embodiments, an organic insulating layer in a pixel area may be partially removed, so that a yellowish screen may be prevented, thereto improve a display quality. In addition, an organic insulating pattern may be formed on a data pattern including the data line, a source electrode and a drain electrode, a coupling capacitance between the data pattern and a common electrode may be prevented or decreased, thereto prevent a data signal delay. The organic insulating pattern may be formed on the thin film transistor to reduce back channel field effect.

### BRIEF DESCRIPTION OF THE DRAWINGS

The above and other features of the inventive concept will become more apparent by describing in detailed exemplary embodiments thereof with reference to the accompanying drawings, in which:

FIG. 1 is a plan view illustrating an exemplary embodiment of a display panel;

FIG. 2 is a plan view illustrating an exemplary embodiment of a first pixel of FIG. 1;

FIG. 3 is a cross-sectional view illustrating an exemplary embodiment of a display panel having a thin film transistor substrate taken along the line I-I′ of FIG. 2;

FIG. 4 is a cross-sectional view illustrating the exemplary embodiment of the thin-film transistor substrate taken along the line I-I′ of FIG. 2;

FIG. 5 is a cross-sectional view illustrating the exemplary embodiment of the thin-film transistor substrate taken along the line II-II′ of FIG. 2;

FIG. 6 is a cross-sectional view illustrating the exemplary embodiment of the thin-film transistor substrate taken along the line III-III′ of FIG. 2; and

FIG. 7 is a cross-sectional view illustrating another exemplary embodiment of a thin-film transistor substrate taken along the line I-I′ of FIG. 2.

### DETAILED DESCRIPTION OF THE INVENTION

Hereinafter, exemplary embodiments of the inventive concept will be explained in detail with reference to the accompanying drawings.

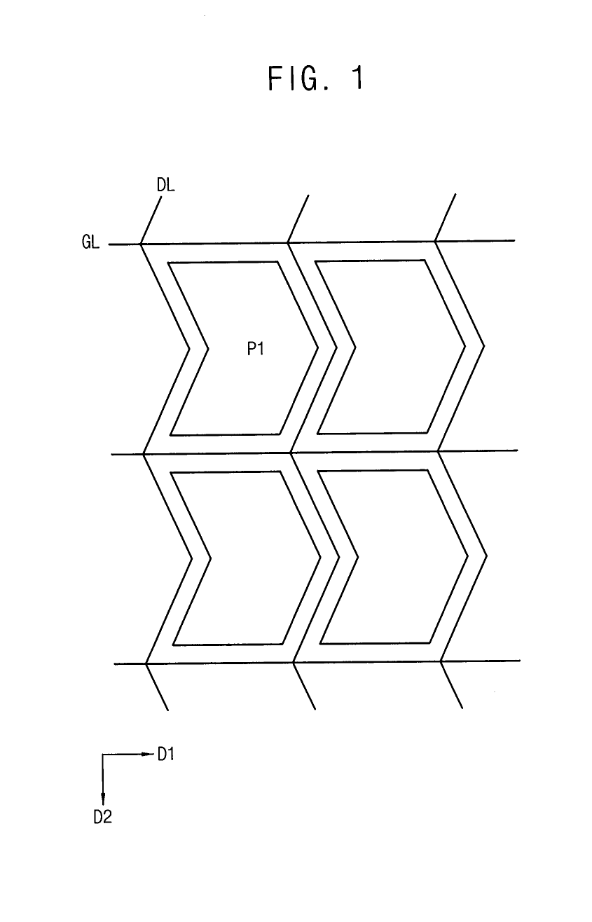

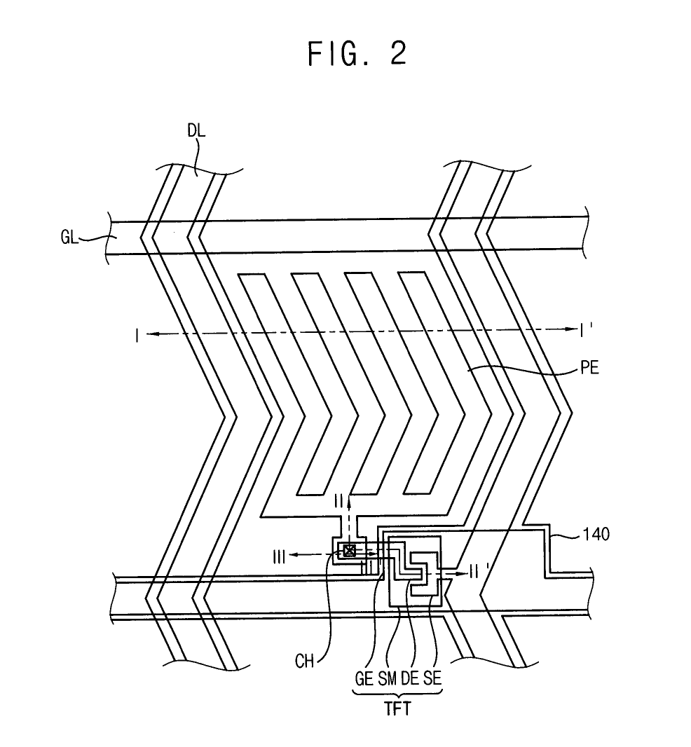

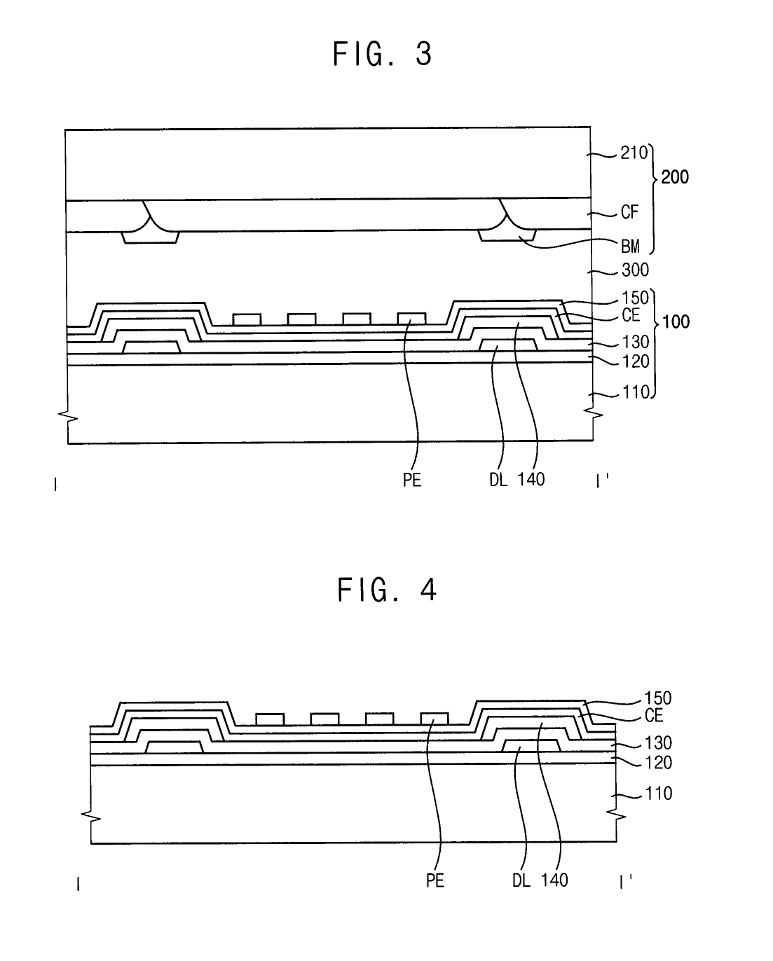

FIG. 1 is a plan view illustrating an exemplary embodiment of a display panel. FIG. 2 is a plan view illustrating an exemplary embodiment of a first pixel of FIG. 1. FIG. 3 is a cross-sectional view illustrating an exemplary embodiment of a display panel including a thin film transistor substrate taken along the line I-I′ of FIG. 2. FIG. 4 is a cross-sectional view illustrating an exemplary embodiment of the thin-film transistor substrate taken along the line I-I′ of FIG. 2.

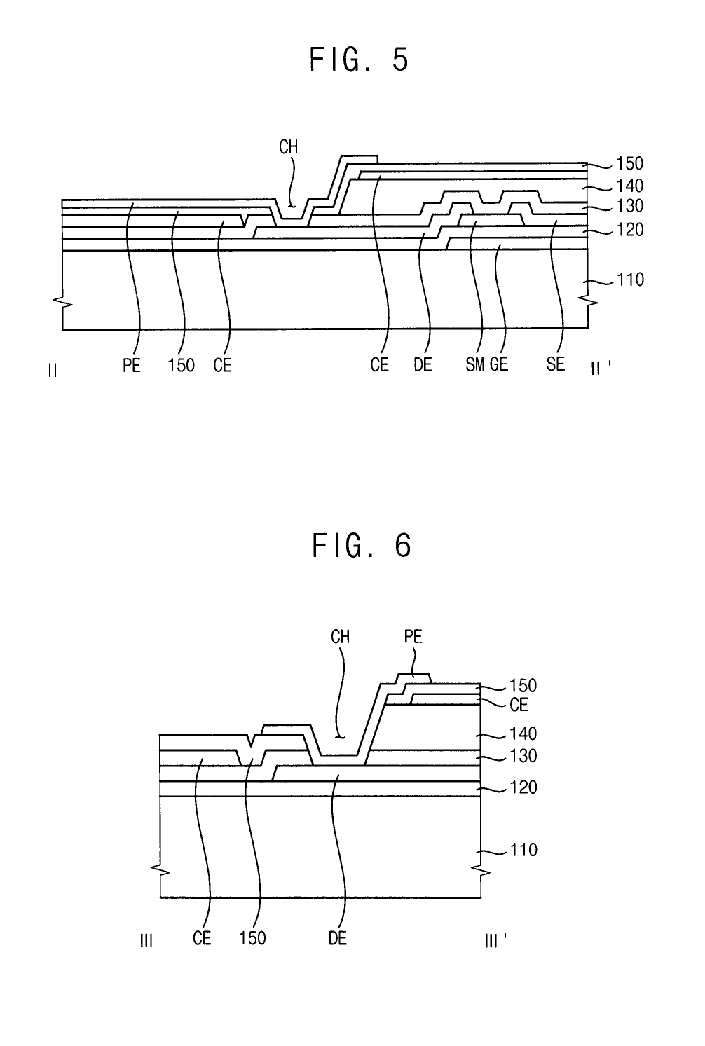

FIG. 5 is a cross-sectional view illustrating an exemplary embodiment of a thin-film transistor substrate taken along the line II-II′ of FIG. 2. FIG. 6 is a cross-sectional view illustrating an exemplary embodiment of a thin-film transistor substrate taken along the line III-III′ of FIG. 2.

Referring to FIG. 1, the display panel includes a plurality of gate lines GL, a plurality of data lines DL and a plurality of pixels.

The gate lines GL may extend in a first direction D1. The data lines DL may extend in a second direction D2, which is substantially crossing the first direction D1. Alternatively, the gate line GL may extend in the second direction D2, and the data line DL may extend in the first direction D1.

The pixels may be arranged in a matrix shape. The pixels may be disposed in areas defined by the gate lines GL and the data lines DL.

Each pixel may be connected to a corresponding gate line GL and a corresponding data line DL adjacent to the pixel.

Each pixel may have a V-shape. Alternatively, the pixel may have a rectangle shape extending in a direction, a Z-shape or the like.

Referring to FIGS. 2 to 6, the display panel includes a first substrate 100, a second substrate 200 and a liquid crystal layer 300.

The first substrate 100 may include a first base substrate 110, a gate insulating layer 120, a data line DL, a first passivation layer 130, an organic insulating pattern 140, a common electrode CE, a second passivation layer 150 and a pixel electrode PE.

The first base substrate 110 may be a transparent insulation substrate. For example, the transparent insulation substrate may be a glass substrate, a plastic substrate or the like. The first base substrate 110 may include a plurality of pixel areas for displaying an image. A plurality of the pixel areas may be disposed in a matrix shape having a plurality of rows and a plurality of columns

Each pixel may further include a switching element. For example, the switching element may be a thin film transistor TFT. The switching element may be connected to the gate line GL and the data line DL adjacent to the switching element. The switching element may be disposed at a crossing area of the gate line GL and the data line DL.

A gate pattern may include a gate electrode GE and the gate line GL. The gate pattern may be disposed on the first base substrate 110. The gate line GL is electrically connected to the gate electrode GE.

The gate insulating layer 120 may be disposed on the first substrate 110 to cover the gate pattern and may insulate the gate pattern.

A semiconductor pattern SM may be disposed on the gate insulating layer 120. The semiconductor pattern SM may overlap the gate electrode GE.

A data pattern may include the data line DL, a source electrode SE and a drain electrode DE. The data pattern may be disposed on the semiconductor pattern SM, which is formed on the gate insulating layer 120. The source electrode SE may overlap the semiconductor pattern SM. The source electrode SE may be electrically connected to the data line DL.

The drain electrode DE may be spaced apart from the source electrode SE on the semiconductor pattern SM. The semiconductor pattern SM may have a conductive channel between the source electrode SE and the drain electrode DE.

The TFT may include the gate electrode GE, the source electrode SE, the drain electrode DE and the semiconductor pattern SM.

The gate insulating layer 120 may include an inorganic insulating material. For example, the gate insulating layer 120 may include silicon oxide (SiOₓ) or silicon nitride (SiNₓ).

The first passivation layer 130 may be disposed on the gate insulating layer 120 to cover the data pattern and may insulate the data pattern.

The first passivation layer 130 may be disposed on the gate line GL, the data line DL and the thin-film transistor TFT. The first passivation layer 130 may be disposed on a whole surface of the first base substrate 110.

The first passivation layer 130 may include an inorganic insulating material. For example, the first passivation layer 130 may include silicon oxide (SiOₓ) or silicon nitride (SiNₓ).

The organic insulating pattern 140 may be disposed on the gate pattern including the gate line GL and the data pattern including the data line DL, and may cover the gate pattern and the data pattern. For example, the organic insulating pattern 140 may cover the gate line GL, the data line DL and the thin-film transistor TFT.

Thus, a coupling capacitance occurs between the gate pattern and the common electrode CE or between the data pattern and the common electrode CE.

The organic insulating pattern 140 may include an opening overlapping with the pixel area. Thus, a remainder area except for an area including the gate line GL, the data line DL and the thin-film transistor TFT may be exposed.

Therefore, an organic material in the pixel area may be removed, so that a yellowish screen may be prevented, thus improving a display quality.

The organic insulating pattern 140 includes a photosensitive organic material. For example, the organic insulating pattern 140 may include a photosensitive organic material such as a photo acryl or the like.

For example, a thickness of the organic insulating pattern 140 may be about 1 μm to about 3 μm. When the thickness of the organic insulating pattern 140 is less than trim, a coupling capacitance between the gate pattern and the common electrode CE or between the data pattern and the common electrode CE may be not reduced. When the thickness of the organic insulating pattern 140 is more than 3 μm, the display panel may be too thick.

For example, a permittivity (c) of the organic insulating pattern 140 may be equal to or less than 4.5. Generally, a capacitance is proportional to the permittivity. Thus, when the permittivity is more than 4.5, a coupling capacitance between the gate pattern and the common electrode CE or between the data pattern and the common electrode CE may be not reduced.

The common electrode CE may be disposed on a whole surface of the first base substrate 110.

For example, the common electrode CE may be overlapped with the data line DL. The organic insulating pattern 140 may be formed between the data line DL and the common electrode CE. Thus, a coupling capacitance between the data line DL and the common electrode CE may be reduced.

For example, the common electrode may include a transparent conductive a transparent conductive material, such as indium tin oxide (ITO), indium zinc oxide (IZO) and aluminum-doped zinc oxide (AZO).

For example, the common electrode CE may have a slit pattern.

The second passivation layer 150 may be disposed on the common electrode CE. The second passivation layer 150 may insulate the common electrode CE and the pixel electrode PE.

The second passivation layer 150 may be disposed on a whole surface of the first base substrate 110.

The second passivation layer 150 may include an inorganic insulating material. For example, the second passivation layer 150 may include silicon oxide (SiOₓ) or silicon nitride (SiNₓ).

The pixel electrode PE may be disposed on the second passivation layer 150.

The pixel electrode PE may be electrically connected to the thin-film transistor TFT through the contact hole CH. The pixel electrode PE may be connected to the drain electrode DE of the thin-film transistor TFT, and a grayscale voltage may be applied to the pixel electrode PE through the thin-film transistor TFT.

The pixel electrode PE may be disposed on the pixel area. For example, the pixel electrode PE may be disposed between adjacent data lines DL.

For example, the pixel electrode PE may include a transparent conductive material, such as indium tin oxide (ITO), indium zinc oxide (IZO) and aluminum-doped zinc oxide (AZO).

For example, the pixel electrode PE may have a slit pattern.

Thus, a grayscale voltage may be applied to the pixel electrode PE and the common electrode CE, thus forming an electric field.

The second substrate 200 may include a second base substrate 210, a color filter CF and a black matrix BM.

The second base substrate 210 may be a transparent insulation substrate. For example, the transparent insulation substrate may be a glass substrate, a plastic substrate or the like.

The color filter CF may be disposed on the second base substrate 210. Adjacent color filters CF may be disposed between adjacent data lines DL.

The color of light may be changed by the color filter CF and the light may penetrate the liquid crystal layer 300. Color filters CF may include a red color filter, green color filter and a blue color filter.

Each of the color filters CF may correspond to one of the pixel areas. Color filters, which are adjacent to each other, may have different colors from each other.

For example, the color filters CF may be overlapped on a border between pixel areas adjacent to each other. Alternatively, the color filters CF may be spaced apart from a border between pixel areas adjacent to each other in the first direction D1. For example, the color filters CF may be formed in a island-shape on the data lines DL.

The black matrix BM is disposed on the color filter CF to block light.

The black matrix BM may be formed to be corresponding to a non-display area of the pixel, so that light provided form an outside may be blocked.

For example, the black matrix BM may be overlapped with the gate line GL, the data line DL and the thin-film transistor TFT.

For example, the black matrix BM may be formed in a metal material having a low transmissivity or a black material including a photosensitive organic material.

For example, the metal material may include molybdenum, titanium, tungsten or an alloy thereof.

For example, the black material may further include a coloring agent such as carbon black, an organic or inorganic pigment, a color mixed pigment or the like.

The liquid crystal layer 300 may be disposed between the first substrate 100 and the second substrate 200.

For example, the liquid crystal layer 300 may include liquid crystal molecules. An alignment of the liquid crystal molecules in the liquid crystal layer 300 may be controlled by an electric field applied between the common electrode CE and the pixel electrode PE. Therefore, a light transmittance of the pixel may be controlled.

It is not illustrated in the figures, the display panel may include an alignment layer to aligning the liquid crystal molecules.

The alignment layer may pre-tilt the liquid crystal molecules of the liquid crystal layer 300.

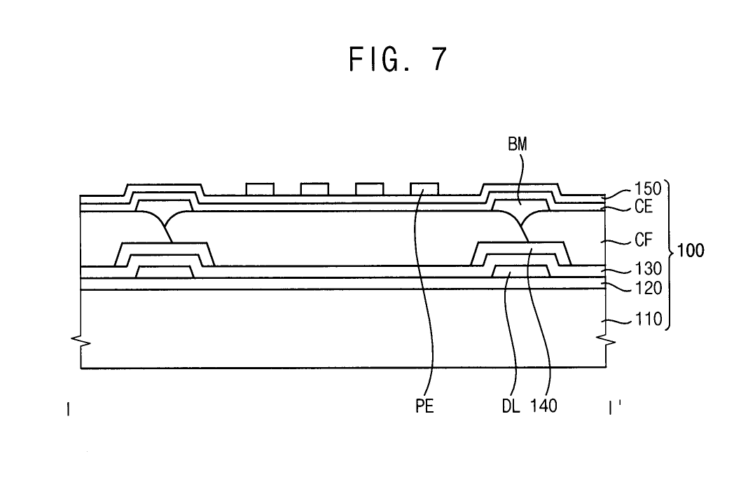

FIG. 7 is a cross-sectional view illustrating an exemplary embodiment of a thin-film transistor substrate taken along the line I-I′ of FIG. 2.

A thin-film transistor substrate according to an exemplary embodiment in FIG. 7 is substantially the same as the thin-film transistor substrate according to an exemplary embodiment in FIGS. 4 to 6. The same reference numerals will be used to refer to the same or like parts as those described in the previous exemplary embodiment in FIGS. 4 to 6 and any further repetitive explanation concerning the above elements will be omitted.

Referring to FIGS. 2 and 7, the first substrate 100 includes a first base substrate 110, a gate insulating layer 120, a data line DL, a first passivation layer 130, an organic insulating pattern 140, a color filter CF, a black matrix BM, a common electrode CE, a second passivation layer 150 and a pixel electrode PE.

For example, the first substrate 100 may have COA (color filter on array) structure that a color filter is formed on a thin-film transistor substrate, and BOA (black matrix on array) structure that a black matrix is formed on a thin-film transistor substrate.

According to an exemplary embodiment, a thin-film transistor substrate and a display panel may be used for a liquid crystal display apparatus, an organic light emitting apparatus or the like.

The foregoing is illustrative of the inventive concept and is not to be construed as limiting thereof. Although a few exemplary embodiments of the inventive concept have been described, those skilled in the art will readily appreciate that many modifications are possible in the exemplary embodiments without materially departing from the novel teachings and advantages of the inventive concept. Accordingly, all such modifications are intended to be included within the scope of the inventive concept as defined in the claims. Therefore, it is to be understood that the foregoing is illustrative of the inventive concept and is not to be construed as limited to the specific exemplary embodiments disclosed, and that modifications to the disclosed exemplary embodiments, as well as other exemplary embodiments, are intended to be included within the scope of the appended claims. The inventive concept is defined by the following claims, with equivalents of the claims to be included therein.

What is claimed is:

1. A thin-film transistor substrate comprising:
a base substrate comprising a plurality of pixel areas;
a gate line disposed on the base substrate, and extended in a first direction;
a data line disposed on the gate line, and extended in a second direction crossing the first direction;
a thin-film transistor connected to the gate line and the data line;
an organic insulating pattern covering the data line and the thin-film transistor, and comprising an opening overlapping with the pixel areas; and
a common electrode disposed on the base substrate.

2. The thin-film transistor substrate of claim 1, wherein the organic insulating pattern covers the gate line.

3. The thin-film transistor substrate of claim 1, further comprising:
a color filter disposed between adjacent data lines.

4. The thin-film transistor substrate of claim 1, further comprising:
a black matrix overlapping with the gate line, the data line and the thin-film transistor.

5. The thin-film transistor substrate of claim 1, wherein the organic insulating pattern comprises a photosensitive organic material.

6. The thin-film transistor substrate of claim 1, wherein a permittivity (e) of the organic insulating pattern is equal to or less than 4.5.

7. The thin-film transistor substrate of claim 1, further comprising:
a gate insulating layer covering the gate line;
a first passivation layer covering the data line;
a second passivation layer covering the common electrode; and
a pixel electrode disposed on the second passivation layer, and overlapping with the pixel areas.

8. The thin-film transistor substrate of claim 7, wherein the pixel electrode is disposed between adjacent data lines.

9. The thin-film transistor substrate of claim 7, wherein the pixel electrode has a slit pattern.

10. A display panel comprising:
a first substrate comprising a plurality of pixel areas and a second substrate facing the first substrate;
a gate line disposed on the first substrate, and extended in a first direction;
a data line disposed on the gate line, and extended in a second direction crossing the first direction;
a thin-film transistor connected to the gate line and the data line;
an organic insulating pattern covering the data line and the thin-film transistor, and comprising an opening overlapping with the pixel areas; and
a common electrode disposed on the first substrate.

11. The display panel of claim 10, wherein the organic insulating pattern covers the gate line.

12. The display panel of claim 10, further comprising:
a color filter disposed between adjacent data lines.

13. The display panel of claim 10, further comprising:
a black matrix overlapping with the gate line, the data line and the thin-film transistor.

14. The display panel of claim 10, wherein the organic insulating pattern comprises a photosensitive organic material.

15. The display panel of claim 10, wherein a permittivity (e) of the organic insulating pattern is equal to or less than 4.5.

16. The display panel of claim 10, further comprising:
a gate insulating layer covering the gate line;
a first passivation layer covering the data line;
a second passivation layer covering the common electrode; and
a pixel electrode disposed on the second passivation layer, and overlapping with the pixel areas.

17. The display panel of claim 16, wherein the pixel electrode is disposed between adjacent data lines.

18. The display panel of claim 16, wherein the pixel electrode has a slit pattern.

19. The thin-film transistor substrate of claim 1, wherein the organic insulating pattern has a thickness of about 1 μm to about 3 μm.

20. The display panel of claim 10, wherein the organic insulating pattern has a thickness of about 1 μm to about 3 μm.
